(19) United States
(12) Patent Application Publication
(10) Pub. No.: US 2020/0086680 A1
(43) Pub. Date: Mar. 19, 2020

(54) LIVE METAL AND METHOD OF MANUFACTURING THE SAME

(71) Applicant: KOREA INSTITUTE OF INDUSTRIAL TECHNOLOGY, Cheonan-si, Chungcheongnam-do (KR)

(72) Inventors: Hyo Soo LEE, Incheon (KR); Hyeong Won SHIN, Incheon (KR); Yeo Reum LEE, Incheon (KR)

(73) Assignee: KOREA INSTITUTE OF INDUSTRIAL TECHNOLOGY, Cheonan-si, Chungcheongnam-do (KR)

(21) Appl. No.: 16/467,725

(22) PCT Filed: Dec. 8, 2017
(86) PCT No.: PCT/KR2017/014416

§ 371 Date: Jun. 7, 2019

(30) Foreign Application Priority Data
Dec. 8, 2016 (KR) 10-2016-0167115

(51) Int. Cl. B44F 9/10; B44C 5/04; B44C 1/14; C23C 14/08; C23C 14/34; C23C 14/04

(52) U.S. Cl. CPC B44F 9/10; B44C 5/0415; C23C 14/04; C23C 14/083; C23C 14/34; B44C 1/14

(57) ABSTRACT

Disclosed herein is a colored metal that includes a metal substrate containing a first metal, an oxidation degree control pattern positioned on the metal substrate, and increasing or decreasing a degree of oxidation of the first metal over time, and a coating film positioned on the metal substrate where the oxidation degree control pattern is positioned, wherein a first region of the metal substrate where the oxidation degree control pattern is present thereon and a second region of the metal substrate where the oxidation degree control pattern is not present thereon exhibit different colors due to a difference in degree of oxidation over time.

### TECHNICAL FIELD

The present invention relates to a live metal and a method of manufacturing the same, and more particularly, to a live metal having a variable color pattern as a degree of oxidation varies over time, and a method of manufacturing the same.

### BACKGROUND ART

With the increasing consumer demand for metal design in recent years, the metal design has been utilized in various fields such as architecture, electronic parts, and household items. Especially, in the field of architecture, studies are ongoing at every level for metal design of appearance or the like of home appliances which plays an important role in the field of exterior materials and interior design.

In the case of a metal product using a conventional casting or sheet metal technique, the color of a metal that can be manufactured using such a technique may be limited. Accordingly, a method of exhibiting the color of a metal in various ways using two or more kinds of metals is also used instead of manufacturing a metal substrate using one kind of metal. However, even when two or more kinds of metals are used, the aesthetics of the whole product design may be damaged as the natural oxidation reaction proceeds according to the use environment. Due to such a problem, a method of preventing discoloration and corrosion using paints or separate coating materials is used in order to control the oxidation reaction. However, since the time for controlling corrosion may be limited, and during that time, a substrate having only the same color as the original metal has to be necessarily used, it is impossible to create a colorful design such as a design that changes over time. Hence, the product design may lag behind fashion and be monotonous.

In recent years, there has been a growing demand for designing a product while taking advantage of the inherent color of metal, rather than seeking an artificial color design using paints or the like. Therefore, a solution to this issue is needed.

In order to solve this problem, U.S. Pat. No. 7,381,622 (hereinafter, referred to as “Prior Art 1”) discloses a method of using a sol-gel solution to produce a patterned metal oxide film.

However, Prior Art 1 does not specifically disclose a method of giving a sense of aesthetics by having a pattern that has various colors according to the degree of oxidation, since a pattern is formed simply by removing a region allowing to cause an oxidation reaction or a region allowing not to cause an oxidation reaction and etching it depending on whether or not to perform an oxidation reaction.

### CITATION LIST

### Patent Literature

[Patent Literature 1]

U.S. Pat. No. 7,381,622

### SUMMARY OF INVENTION

### Technical Problem

It is an object of the present invention to provide a live metal (colored metal) that enables a pattern formed on a metal substrate to have various colors by controlling a degree of oxidation reaction over time, and a method of manufacturing the same.

The present invention is not limited to the above-mentioned object, and other objects of the present invention can be clearly understood by those skilled in the art to which the present invention pertains from the following description.

### Solution to Problem

To accomplish the above object, in accordance with one aspect of the present invention, there is provided a colored metal that includes a metal substrate containing a first metal, an oxidation degree control pattern positioned on the metal substrate, and increasing or decreasing a degree of oxidation of the first metal over time, and a coating film positioned on the metal substrate where the oxidation degree control pattern is positioned, wherein a first region of the metal substrate where the oxidation degree control pattern is present thereon and a second region of the metal substrate where the oxidation degree control pattern is not present thereon exhibit different colors due to a difference in degree of oxidation over time.

In an embodiment of the present invention, the first metal may be at least one selected from the group consisting of copper (Cu), zinc (Zn), aluminum (Al), iron (Fe), lead (Pb), titanium (Ti), and an alloy containing the same.

In an embodiment of the present invention, the oxidation degree control pattern may include a carbon-based organic material.

For example, the carbon-based organic material may be at least one selected from the group consisting of carbon, carbon nanotube, graphite, carbon black, carbon fiber, and graphene.

In an embodiment of the present invention, the first region of the metal substrate may correspond to an entire one surface of the metal substrate, and the second region of the metal substrate may correspond to all surfaces of the metal substrate except for the first region of the metal substrate.

In an embodiment of the present invention, the first region of the metal substrate may correspond to a portion of one surface of the metal substrate, and the second region of the metal substrate may correspond to all surfaces of the metal substrate except for the first region of the metal substrate.

In another embodiment of the present invention, the first region of the metal substrate may correspond to a portion of all surfaces of the metal substrate, and the second region of the metal substrate may correspond to a remaining portion of all surfaces of the metal substrate except for the first region of the metal substrate.

To accomplish the above object of the present invention, the coating film may be at least one of a colorless film, a single-color film, and a multicolor film.

In an embodiment of the present invention, the coating film may include at least one selected from the group consisting of copper (Cu), zinc (Zn), aluminum (Al), iron (Fe), lead (Pb), titanium (Ti), and an alloy containing the same.

In another embodiment of the present invention, the coating film may include at least one selected from the group consisting of copper oxide (CuO), zinc oxide (ZnO), aluminum oxide (A1203), iron oxide (II) (FeO), iron oxide (III) (Fe₂O₃), lead suboxide (Pb₂O), lead monoxide (PbO), lead dioxide (PbO₂), titanium oxide (TiO), and titanium dioxide (TiO₂).

To accomplish the above object, in accordance with another aspect of the present invention, there is provided a method of manufacturing a colored metal, which includes preparing a metal substrate containing a first metal, forming an oxidation degree control pattern on the metal substrate, and forming a coating film on the metal substrate where the oxidation degree control pattern is formed, wherein a first region of the metal substrate where the oxidation degree control pattern is present thereon and a second region of the metal substrate where the oxidation degree control pattern is not present thereon exhibit different colors due to a difference in degree of oxidation over time.

In an embodiment of the present invention, the first metal may be at least one selected from the group consisting of copper (Cu), zinc (Zn), aluminum (Al), iron (Fe), lead (Pb), titanium (Ti), and an alloy containing the same.

In an embodiment of the present invention, the oxidation degree control pattern may include a carbon-based organic material.

In another embodiment of the present invention, the carbon-based organic material may be at least one selected from the group consisting of carbon, carbon nanotube, graphite, carbon black, carbon fiber, and graphene.

In an embodiment of the present invention, the forming an oxidation degree control pattern on the metal substrate may include bonding an adhesive containing the carbon-based organic material and an adhesive material to the metal substrate, and performing low-temperature heat treatment on a region on the metal substrate to which the adhesive containing the carbon-based organic material is bonded, wherein the adhesive material may be removed and the carbon-based organic material may remain.

In an embodiment of the present invention, the low-temperature heat treatment may be performed at a temperature of 40° C. to 70° C.

In another embodiment of the present invention, the coating film may be at least one of a colorless film, a single-color film, and a multicolor film.

### Advantageous Effects of Invention

In accordance with exemplary embodiments of the present invention, it is possible to provide a colored metal capable of forming a pattern on the surface of at least one metal in a simple manner while the color of the pattern varies due to the difference in degree of oxidation over time.

As an effect of the present invention, it is possible to position an oxidation control pattern on a metal substrate so that the degree of oxidation can be different even though one metal substrate is used, and to design the metal substrate having various colors.

As an effect of the present invention, it is possible to position a coating film on the metal substrate on which the oxidation degree control pattern is formed so that the coating film can also be a colorless, single color, and multicolor film, and to express the color of the pattern formed on the colored metal in more various manners by variously expressing the color of the coating film, as well as controlling the degree of oxidation of the metal substrate.

In accordance with exemplary embodiments of the present invention, since a metal substrate is designable in various manners using the difference in degree of oxidation over time, it is possible to use the metal substrate in all fields that can use metal design including building exterior materials and the appearance of home appliances.

As another effect of the present invention, it is possible to manufacture a colored metal exhibiting various colors by causing an oxidation reaction immediately without the passage of time, using artificial chemical oxidation, instead of natural oxidation.

The present invention is not limited to the above effects, and it should be understood that the present invention includes all effects which can be inferred from the detailed description of the present invention or the configuration of the invention defined by the appended claims.

### BRIEF DESCRIPTION OF DRAWINGS

FIG. 1 is a cross-sectional view of a colored metal.

FIG. 2 is a flowchart illustrating a method of manufacturing a colored metal.

FIG. 3 is a photograph illustrating a metal substrate (copper substrate) to which a carbon-based organic material is bonded.

FIG. 4 is a photograph illustrating a metal substrate on which a coating film is formed by sputtering a metal oxide (TiO₂) after a carbon-based organic material is bonded to the metal substrate and low-temperature heat treatment is then performed thereon.

FIG. 5 is a photograph illustrating a metal substrate subjected to oxidation acceleration by high-temperature heat treatment of the metal substrate on which a coating film is formed by sputtering a metal oxide (TiO₂).

### DESCRIPTION OF EMBODIMENTS

Reference will now be made in detail to exemplary embodiments of the present invention, examples of which are illustrated in the accompanying drawings. The present invention may, however, be embodied in different forms and should not be construed as limited to the embodiments set forth herein. For clear explanation of the present invention, parts irrelevant to the description may be omitted in the drawings, and like reference numerals refer to like parts throughout the specification.

In the whole specification, it will be understood that when an element is referred to as being “connected (joined, contacted, or coupled)” to another element, it can be “directly connected” to the other element or it can be “indirectly connected” to the other element with other elements being interposed therebetween. In addition, it will be understood that when a component is referred to as “comprising or including” any component, it does not exclude other components, but can further comprise or include the other components unless otherwise specified.

The terminology used in the present disclosure is for the purpose of describing particular embodiments only and is not intended to limit the invention. As used in the disclosure and the appended claims, the singular forms “a”, “an” and “the” are intended to include the plural forms as well, unless context clearly indicates otherwise. It will be further understood that the terms “comprises/includes” and/or “comprising/including” when used in this specification, specify the presence of stated features, integers, steps, operations, elements, components, and/or groups thereof, but do not preclude the presence or addition of one or more other features, integers, steps, operations, elements, components, and/or groups thereof.

The term “colored metal” used herein is the same concept as a “live metal” and means a metal substrate in which two or more colors are exhibited on one metal substrate, and various colors can be exhibited by a difference in degree of oxidation over time or due to chemical stimulation.

Hereinafter, a colored metal according to the present invention will be described in detail with reference to the accompanying drawings.

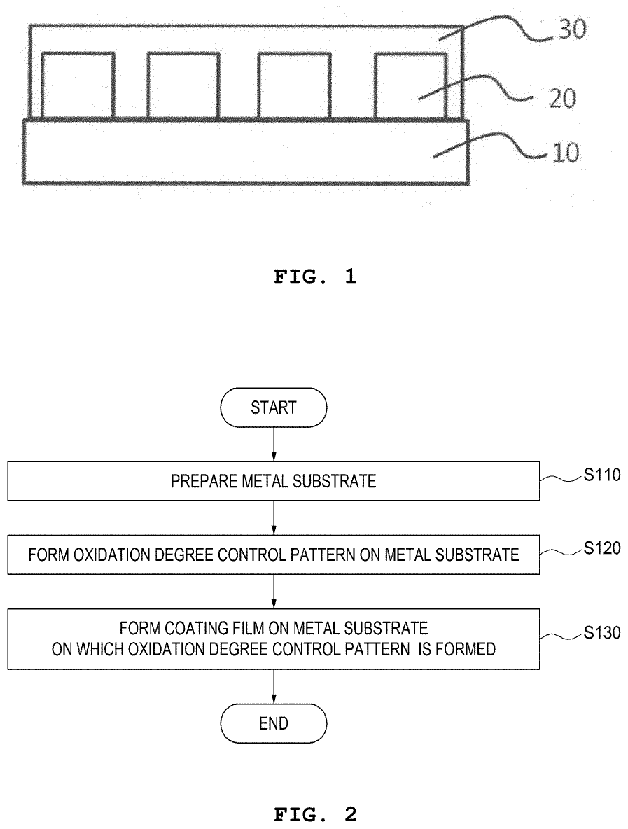

FIG. 1 is a cross-sectional view of a colored metal. Referring to FIG. 1, the colored metal includes a metal substrate 10 containing a first metal, an oxidation degree control pattern 20 positioned on the metal substrate and increasing or decreasing the degree of oxidation of the first metal over time, and a coating film 30 positioned on the metal substrate where the oxidation degree control pattern is positioned. A first region of the metal substrate where the oxidation degree control pattern is present thereon and a second region of the metal substrate where the oxidation degree control pattern is not present thereon may exhibit different colors due to a difference in degree of oxidation over time.

In the metal substrate 10 containing the first metal, the first metal may be at least one selected from the group consisting of copper (Cu), zinc (Zn), aluminum (Al), iron (Fe), lead (Pb), titanium (Ti), and an alloy containing the same.

In this case, it is more preferable to use copper as the first metal. In the case where copper having a relatively high degree of oxidation is used, when the oxidation degree control pattern is positioned thereon, the difference in the degree of oxidation over time may be more clearly and distinctly expressed depending on whether or not the oxidation degree control pattern is present on the metal substrate.

The oxidation degree control pattern 20 may be formed as illustrated in FIG. 1, but the present invention is not limited thereto. The oxidation degree control pattern may be positioned in a specific area to be designed by a user as well as being positioned in an entire surface region, a partial edge area, or a part of the surface of the metal substrate.

The oxidation degree control pattern may include a carbon-based organic material. The carbon-based organic material may be at least one selected from the group consisting of carbon, carbon nanotube, graphite, carbon black, carbon fiber, and graphene, but the present invention is not limited thereto. Any material may be used as the carbon-based organic material as long as it can increase or decrease the degree of oxidation of the metal.

The region of the metal substrate may be designated depending on whether or not the oxidation degree control pattern is positioned on the metal substrate. In more detail, the first region of the metal substrate may be defined by when the oxidation degree control pattern is present on the metal substrate, and the second region of the metal substrate may be defined by when the oxidation degree control pattern is not present on the metal substrate.

For example, the first region of the metal substrate may correspond to the entire one surface of the metal substrate, and the second region of the metal substrate may correspond to all surfaces of the metal substrate except for the first region of the metal substrate.

In another example, the first region of the metal substrate may correspond to a portion of one surface of the metal substrate, and the second region of the metal substrate may correspond to all surfaces of the metal substrate except for the first region of the metal substrate.

In a further example, the first region of the metal substrate may correspond to a portion of all surfaces of the metal substrate, and the second region of the metal substrate may correspond to a remaining portion of all surfaces of the metal substrate except for the first region of the metal substrate.

However, the first and second regions of the metal substrate are not limited to the above-mentioned regions, but they may be variously designated according to the shape of the pattern to be formed on the metal substrate. Accordingly, it is possible to provide a colored metal having various types of patterns formed thereon and exhibiting two or more colors over time or by chemical stimulation.

The coating film 30 may be at least one of a colorless film, a single-color film, and a multicolor film.

In the present invention, when the coating film is a single-color or multicolor film, it is possible to produce a colored metal exhibiting various colors depending on the color of the coating film itself in the absence of the oxidation reaction. When the oxidation reaction proceeds over time or by chemical stimulation, the metal substrate is exhibited in various colors depending on whether or not the oxidation degree control pattern exists, thereby providing a colored metal capable of creating various designs even though the service life thereof is long.

For example, the coating film may include at least one selected from the group consisting of copper (Cu), zinc (Zn), aluminum (Al), iron (Fe), lead (Pb), titanium (Ti), and an alloy containing the same.

In another example, the coating film may include at least one selected from the group consisting of copper oxide (CuO), zinc oxide (ZnO), aluminum oxide (Al₂O₃), iron oxide (II) (FeO), iron oxide (III) (Fe₂O₃), lead suboxide (Pb₂O), lead monoxide (PbO), lead dioxide (PbO₂), titanium oxide (TiO), and titanium dioxide (TiO₂).

In a further example, the coating film may include at least one selected from the group consisting of acrylate, glass, polycarbonate, and styrene.

However, the material constituting the coating film is not limited to the materials listed above, and may be a colorless, single-color, or multicolor material. In addition, any material may be used as long as it does not cause a side reaction with the metal substrate.

Hereinafter, a method of manufacturing a pattern of a metal substrate according to the present invention will be described in detail with reference to the accompanying drawings.

FIG. 2 is a flowchart illustrating a method of manufacturing a colored metal.

Referring to FIG. 2, there is provided a method of manufacturing a colored metal, which includes a step of preparing a metal substrate containing a first metal (S110), a step of forming an oxidation degree control pattern on the metal substrate (S120), and a step of forming a coating film on the metal substrate where the oxidation degree control pattern is formed (S130), wherein a first region of the metal substrate where the oxidation degree control pattern is present thereon and a second region of the metal substrate where the oxidation degree control pattern is not present thereon may exhibit different colors due to a difference in degree of oxidation over time.

First, in the step of preparing a metal substrate containing a first metal (S110), the first metal may be at least one selected from the group consisting of copper (Cu), zinc (Zn), aluminum (Al), iron (Fe), lead (Pb), titanium (Ti), and an alloy containing the same.

In this case, it is more preferable to use copper as the first metal. In the case where copper having a relatively high degree of oxidation is used, when the oxidation degree control pattern is positioned thereon, the difference in the degree of oxidation over time may be more clearly and distinctly expressed depending on whether or not the oxidation degree control pattern is present on the metal substrate.

Next, the step of forming an oxidation degree control pattern on the metal substrate (S120) may correspond to a step of first positioning the oxidation degree control pattern on the metal substrate to be patterned.

When two or more kinds of metals are used, it is general to use a method of directly coating different kinds of metals on the surface of one metal. However, when separate treatment is not performed between two or more kinds of metals, it may be difficult to control an oxidation rate in the process of natural oxidation over time and to exhibit various colors due to the different in oxidation rate.

In contrast, when the step of forming an oxidation degree control pattern is performed, it is possible to form a pattern having more various colors than the type of metal used on the surface of one metal substrate by regulating the type and amount of an oxidation control material to control an oxidation rate.

In this case, the oxidation degree control pattern may include a carbon-based organic material.

For example, the carbon-based organic material may be at least one selected from the group consisting of carbon, carbon nanotube, graphite, carbon black, carbon fiber, and graphene.

The step of forming an oxidation degree control pattern on the metal substrate (S120) will be described below in more detail.

The step of forming an oxidation degree control pattern on the metal substrate may include a step of bonding an adhesive containing the carbon-based organic material and an adhesive material to the metal substrate, and a step of performing low-temperature heat treatment on a region on the metal substrate to which the adhesive containing the carbon-based organic material is bonded, in order to remove the adhesive material and leave the carbon-based organic material.

For example, in the step of bonding an adhesive containing the carbon-based organic material and an adhesive material to the metal substrate, a carbon tape may be used as the adhesive containing the carbon-based organic material, or an adhesive solution containing a carbon-based organic material may be applied to the metal substrate.

The adhesive material contained in the adhesive may include at least one selected from the group consisting of ethylene-propylene rubber, ethylene-propylene-diene rubber, polybutadiene rubber, polyisoprene, ethylene high-content propylene-ethylene block copolymer, poly (1-butene), polypropylene, polyethylene, ethylene-butene rubber, ethylene-propylene-ethyl idenenorbornene terpolymer, ethylene-propylene-hexadiene terpolymer, and ethylene-propylene-octadiene terpolymer. However, the present invention is not limited to the adhesive materials listed above, and any material may be used as long as it is attachable to the metal substrate, acts as a binder of the carbon-based organic material, and does not cause a side reaction with the carbon-based organic material.

For example, in the step of performing low-temperature heat treatment on a region on the metal substrate to which the adhesive containing the carbon-based organic material is bonded, the low-temperature heat treatment may be performed at a temperature of 40° C. to 70° C.

The color exhibited by the progress of oxidation reaction may vary depending on a temperature condition in which the low-temperature heat treatment is performed on the region on the metal substrate to which the adhesive containing the carbon-based organic material is bonded.

In addition, the low-temperature heat treatment is performed to remove adhesive materials or foreign substances except for the carbon-based organic material, thereby preventing a side reaction due to the presence of adhesive materials or foreign substances and controlling the degree of oxidation only using the carbon-based organic material. In this case, the temperature for the low-temperature heat treatment is not limited to the above-mentioned temperature range. However, if the heat treatment is performed on the surface of the first metal at a temperature lower than 40° C., the adhesive materials or foreign substances may not be completely removed and partially left, which may lead to a side reaction so as not to control the degree of oxidation of the pattern formed in the following steps. Hence, it may be difficult to realize various colors on the metal substrate depending on the degree of oxidation.

If the temperature for the heat treatment is higher than 70° C., the carbon-based organic material may also be removed and the metal substrate may be excessively oxidized or denatured. Therefore, it is preferable to perform the low-temperature heat treatment within the above temperature range.

The step of forming a coating film on the metal substrate where the oxidation degree control pattern is formed (S130) is a step of realizing various colors of the colored metal from before the oxidation reaction as well as after the oxidation reaction, wherein it is possible to have a pattern, the color of which further varying depending on the degree of oxidation.

In the present invention, the coating film may be at least one of a colorless film, a single-color film, and a multicolor film.

In the present invention, when the coating film is a single-color or multicolor film, it is possible to produce a colored metal exhibiting various colors depending on the color of the coating film itself in the absence of the oxidation reaction. When the oxidation reaction proceeds over time or by chemical stimulation, the metal substrate is exhibited in various colors depending on whether or not the oxidation degree control pattern exists, thereby providing a colored metal capable of creating various designs even though the service life thereof is long.

For example, the coating film may include at least one selected from the group consisting of copper (Cu), zinc (Zn), aluminum (Al), iron (Fe), lead (Pb), titanium (Ti), and an alloy containing the same.

In another example, the coating film may include at least one selected from the group consisting of copper oxide (CuO), zinc oxide (ZnO), aluminum oxide (Al₂O₃), iron oxide (II) (FeO), iron oxide (III) (Fe₂O₃), lead suboxide (Pb₂O), lead monoxide (PbO), lead dioxide (PbO₂), titanium oxide (TiO), and titanium dioxide (TiO₂).

In a further example, the coating film may include at least one selected from the group consisting of acrylate, glass, polycarbonate, and styrene.

However, the material constituting the coating film is not limited to the materials listed above, and may be a colorless, single-color, or multicolor material. In addition, any material may be used as long as it does not cause a side reaction with the metal substrate.

For example, as the method of forming the coating film, various coating methods may be used such as sputtering, spin-coating, spraying, and dip-coating. However, from among the coating methods, a coating method that may damage the metal substrate composed of the first metal and the oxidation degree control pattern may not be used.

In particular, the sputtering refers to a method in which an ion impact is applied to a metal to cause atoms or molecules constituting the metal to protrude and adhere to a surface of a metal substrate. When the sputtering is performed to form the coating film, it is possible to adjust the amount and thickness of the attached metal according to the rate and time of the sputtering.

However, the thickness varying depending on the sputtering condition or the sputtering is not limited to the above range, and the sputtering condition can be adjusted to realize a desired pattern color on the metal substrate.

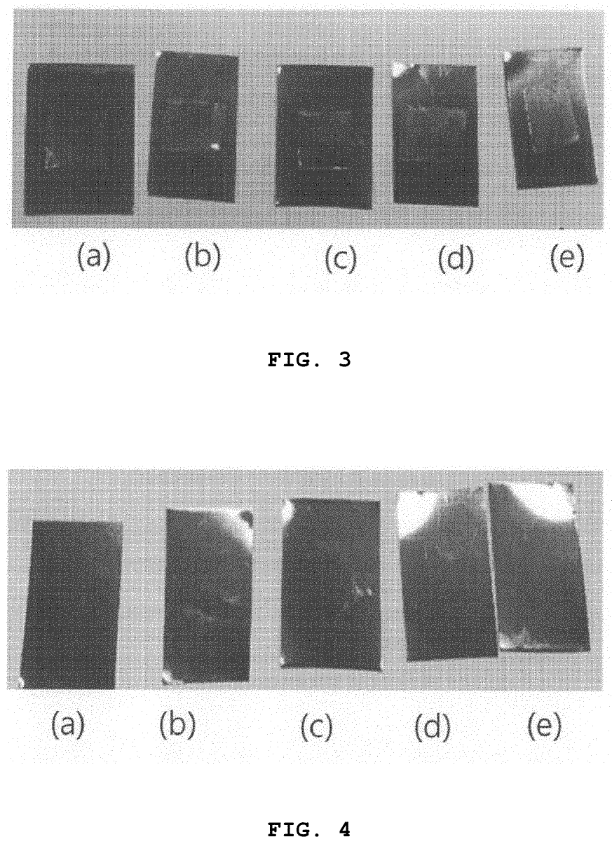

Hereinafter, examples of the present invention and a comparative example will be described with reference to FIGS. 3 to 5.

FIG. 3 is a photograph illustrating a metal substrate (copper substrate) to which a carbon-based organic material is bonded.

FIG. 4 is a photograph illustrating a metal substrate on which a coating film is formed by sputtering a metal oxide (TiO₂) after a carbon-based organic material is bonded to the meal substrate and low-temperature heat treatment is then performed thereon.

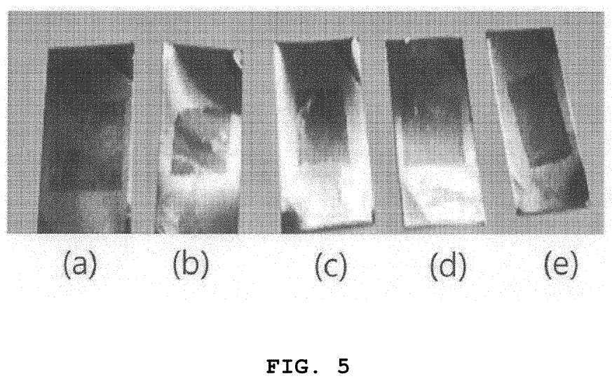

FIG. 5 is a photograph illustrating a metal substrate subjected to oxidation acceleration by high-temperature heat treatment of the metal substrate on which a coating film is formed by sputtering a metal oxide (TiO₂).

### EXAMPLE 1

1. Formation of Oxidation Degree Control Pattern on Metal Substrate

After attaching a carbon tape to a thin copper plate, the surface of the thin copper plate having the carbon tape attached thereto is subjected to low-temperature heat treatment at 40° C. to leave a carbon-based organic material of the carbon tape. Then, the carbon tape is removed to form an oxidation degree control pattern.

2. Coating Film Formation

TiO₂ is sputtered on the thin copper plate containing only the carbon-based organic material for 30 minutes to form a coating film.

3. Oxidation Acceleration Treatment

The surface of the thin copper plate having the coating film formed thereon is subjected to high-temperature heat treatment at a temperature of 250° C. for 30 minutes.

### EXAMPLE 2

The same procedure proceeds as in Example 1 except that the low-temperature heat treatment is performed at a temperature of 50° C.

### EXAMPLE 3

The same procedure proceeds as in Example 1 except that the low-temperature heat treatment is performed at a temperature of 60° C.

### EXAMPLE 4

The same procedure proceeds as in Example 1 except that the low-temperature heat treatment is performed at a temperature of 70° C.

### COMPARATIVE EXAMPLE 1

The same procedure proceeds as in Example 1 except that the low-temperature heat treatment is not performed.

The description thereof will be given with reference to FIGS. 3 to 5.

In Example 1, the state when forming the oxidation degree control pattern on the metal substrate corresponds to FIG. 3(b), the state after forming the coating film corresponds to FIG. 4(b), and the state after the oxidation acceleration corresponds to FIG. 5(b).

In Example 2, the state when forming the oxidation degree control pattern on the metal substrate corresponds to FIG. 3(c), the state after forming the coating film corresponds to FIG. 4(c), and the state after the oxidation acceleration corresponds to FIG. 5(c).

In Example 3, the state when forming the oxidation degree control pattern on the metal substrate corresponds to FIG. 3(d), the state after sputtering the metal corresponds to FIG. 4(d), and the state after forming the coating film corresponds to FIG. 5(d).

In Example 4, the state when forming the oxidation degree control pattern on the metal substrate corresponds to FIG. 3(e), the state after sputtering the metal corresponds to FIG. 4(e), and the state after forming the coating film corresponds to FIG. 5(e).

In Comparative Example 1, the state when the oxidation degree control pattern is not properly formed on the metal substrate and the adhesive material is present corresponds to FIG. 3(a), the state after sputtering the metal corresponds to FIG. 4(a), and the state after forming the coating film corresponds to FIG. 5(a).

It can be seen in the above Examples and Comparative example that no difference in color on the metal substrate is observed after metal sputtering.

However, referring to FIG. 5 illustrating after oxidation acceleration through high-temperature heat treatment, no difference in color on the metal substrate is observed in Comparative Example since the coating film is formed in the state in which the low-temperature heat treatment is not performed so that the carbon-based organic material is not left by the removal of the carbon tape and the oxidation degree control pattern is not properly formed. On the other hand, in all Examples in which the low-temperature heat treatment is performed, the coating film is formed after the oxidation degree control pattern is properly formed, and it can be therefore seen that the colors of the patterned portion and the metal substrate are noticeably different from each other. Thus, it is possible to manufacture a colored metal having a pattern of various colors depending on whether or not the oxidation degree control pattern is formed.

The above-mentioned embodiments of the present invention are merely examples, and it will be understood by those skilled in the art that various modifications may be made without departing from the spirit and scope or essential features of the invention. Therefore, it should be understood that the embodiments described above are for purposes of illustration only in all aspects and are not intended to limit the scope of the present invention. For example, each component described in a single form may be implemented in a distributed form, and similarly, components described in the distributed form may be implemented in a combined form.

The scope of the present invention is defined by the appended claims, and it should be construed that all modifications or variations derived from the meaning, scope, and equivalent concept of the claims fall within the scope of the invention.

### REFERENCE SIGNS LIST

10: metal substrate

20: oxidation degree control pattern

30: coating film

What is claimed is:

1. A colored metal comprising:
a metal substrate containing a first metal;
an oxidation degree control pattern positioned on the metal substrate, and increasing or decreasing a degree of oxidation of the first metal over time; and
a coating film positioned on the metal substrate where the oxidation degree control pattern is positioned,
wherein a first region of the metal substrate where the oxidation degree control pattern is present thereon and a second region of the metal substrate where the oxidation degree control pattern is not present thereon exhibit different colors due to a difference in degree of oxidation over time.

2. The colored metal according to claim 1, wherein the first metal is at least one selected from the group consisting of copper (Cu), zinc (Zn), aluminum (Al), iron (Fe), lead (Pb), titanium (Ti), and an alloy containing the same.

3. The colored metal according to claim 1, wherein the oxidation degree control pattern comprises a carbon-based organic material.

4. The colored metal according to claim 3, wherein the carbon-based organic material is at least one selected from the group consisting of carbon, carbon nanotube, graphite, carbon black, carbon fiber, and graphene.

5. The colored metal according to claim 1, wherein the first region of the metal substrate corresponds to an entire one surface of the metal substrate, and the second region of the metal substrate corresponds to all surfaces of the metal substrate except for the first region of the metal substrate.

6. The colored metal according to claim 1, wherein the first region of the metal substrate corresponds to a portion of one surface of the metal substrate, and the second region of the metal substrate corresponds to all surfaces of the metal substrate except for the first region of the metal substrate.

7. The colored metal according to claim 1, wherein the first region of the metal substrate corresponds to a portion of all surfaces of the metal substrate, and the second region of the metal substrate corresponds to a remaining portion of all surfaces of the metal substrate except for the first region of the metal substrate.

8. The colored metal according to claim 1, wherein the coating film is at least one of a colorless film, a single-color film, and a multicolor film.

9. The colored metal according to claim 1, wherein the coating film comprises at least one selected from the group consisting of copper (Cu), zinc (Zn), aluminum (Al), iron (Fe), lead (Pb), titanium (Ti), and an alloy containing the same.

10. The colored metal according to claim 1, wherein the coating film comprises at least one selected from the group consisting of copper oxide (CuO), zinc oxide (ZnO), aluminum oxide (Al₂O₃), iron oxide (II) (FeO), iron oxide (III) (Fe₂O₃), lead suboxide (Pb₂O), lead monoxide (PbO), lead dioxide (PbO₂), titanium oxide (TiO), and titanium dioxide (TiO₂).

11. A method of manufacturing a colored metal, comprising:
preparing a metal substrate containing a first metal;
forming an oxidation degree control pattern on the metal substrate; and
forming a coating film on the metal substrate where the oxidation degree control pattern is formed,
wherein a first region of the metal substrate where the oxidation degree control pattern is present thereon and a second region of the metal substrate where the oxidation degree control pattern is not present thereon exhibit different colors due to a difference in degree of oxidation over time.

12. The method according to claim 11, wherein the first metal is at least one selected from the group consisting of copper (Cu), zinc (Zn), aluminum (Al), iron (Fe), lead (Pb), titanium (Ti), and an alloy containing the same.

13. The method according to claim 11, wherein the oxidation degree control pattern comprises a carbon-based organic material.

14. The method according to claim 13, wherein the carbon-based organic material is at least one selected from the group consisting of carbon, carbon nanotube, graphite, carbon black, carbon fiber, and graphene.

15. The method according to claim 13, wherein the forming an oxidation degree control pattern on the metal substrate comprises:
bonding an adhesive containing the carbon-based organic material and an adhesive material to the metal substrate; and
performing low-temperature heat treatment on a region on the metal substrate to which the adhesive containing the carbon-based organic material is bonded,
wherein the adhesive material is removed and the carbon-based organic material remains.

16. The method according to claim 15, wherein the low-temperature heat treatment is performed at a temperature of 40° C. to 70° C.

17. The method according to claim 11, wherein the coating film is at least one of a colorless film, a single-color film, and a multicolor film.
